(19) United States
(12) Patent Application Publication
(10) Pub. No.: US 2024/0404978 A1
(43) Pub. Date: Dec. 5, 2024

(54) WIRING BOARD, SEMICONDUCTOR DEVICE, AND WIRING BOARD MANUFACTURING METHOD

(71) Applicant: SHINKO ELECTRIC INDUSTRIES CO., LTD., Nagano-shi (JP)

(72) Inventor: Masaya Takizawa, Nagano (JP)

(21) Appl. No.: 18/671,520

(22) Filed: May 22, 2024

(30) Foreign Application Priority Data
Jun. 2, 2023 (JP) 2023-091620

(51) Int. Cl. H01L 23/00; H01L 21/48; H01L 23/498; H05K 1/11

(52) U.S. Cl. CPC H01L 24/32; H01L 21/4857; H01L 21/563; H01L 23/49838; H01L 23/49866; H01L 24/83; H05K 1/112; H01L 24/16; H01L 24/73; H01L 2224/16227; H01L 2224/16238; H01L 2224/32238; H01L 2224/73204; H01L 2224/81395; H01L 2224/83385; H01L 2224/83395; H05K 2201/09827; H05K 2201/099

(57) ABSTRACT

A wiring board includes an insulating layer, a connection terminal, and a wiring structure. The insulating layer includes a first surface and a second surface on an opposite side of the first surface, and includes an opening portion that is formed so as to penetrate through the first surface and the second surface. The connection terminal is arranged in the opening portion. The wiring structure is connected to the connection terminal. The connection terminal includes a pad that is formed in the opening portion and that has a bottom surface located on a same plane as the second surface of the insulating layer, and a surface treatment layer that covers the pad. The pad protrudes from the first surface of the insulating layer, and the surface treatment layer forms a gap between the surface treatment layer and an inner wall surface of the opening portion.

### CROSS-REFERENCE TO RELATED APPLICATION

This application is based upon and claims the benefit of priority of the prior Japanese Patent Application No. 2023-091620, filed on Jun. 2, 2023, the entire contents of which are incorporated herein by reference.

### FIELD

The embodiment discussed herein is related to a wiring board, a semiconductor device, and a wiring board manufacturing method.

### BACKGROUND

In general, a connection terminal for a semiconductor chip is formed on a wiring board on which the semiconductor chip is to be mounted. The connection terminal is a protrusion that is electrically connected to a wiring structure of the wiring board, and protrudes outward from an opening portion that is formed in an insulating layer that is an uppermost layer of the wiring board.

When the semiconductor chip is mounted on the wiring board, an electrode of the semiconductor chip is connected to the connection terminal by, for example, solder. Further, a space between the wiring board and the semiconductor chip is filled with an underfill material such that the underfill material comes into contact with a lower surface of the semiconductor chip and the insulating layer that forms the uppermost layer of the wiring board.
Patent Literature 1: Japanese Laid-open Patent Publication No. 2020-150114

However, in the technology as described above, there is room for improvement in increasing adhesiveness of the underfill material to the insulating layer.

### SUMMARY

According to an aspect of an embodiment, a wiring board includes an insulating layer that includes a first surface and a second surface on an opposite side of the first surface, and includes an opening portion that is formed so as to penetrate through the first surface and the second surface; a connection terminal that is arranged in the opening portion; and a wiring structure that is formed on the second surface of the insulating layer and connected to the connection terminal, wherein the connection terminal includes a pad that is formed in the opening portion and that has a bottom surface located on a same plane as the second surface of the insulating layer; and a surface treatment layer that covers an upper surface and side surfaces of the pad, the pad protrudes from the first surface of the insulating layer at a position of the opening portion, and the surface treatment layer forms a gap between the surface treatment layer and an inner wall surface of the opening portion.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a wiring board according to one embodiment;

FIG. 2 is an enlarged view of a periphery of a connection terminal;

FIG. 3 is a flowchart illustrating a method of manufacturing a semiconductor device according to one embodiment;

FIG. 4 is a diagram illustrating a specific example of a support body;

FIG. 5 is a diagram illustrating a specific example of a resist layer formation process;

FIG. 6 is a diagram illustrating a specific example of an outer peripheral portion etching process;

FIG. 7 is a diagram illustrating a specific example of a resist layer stripping process;

FIG. 8 is a diagram illustrating a specific example of an insulating layer formation process;

FIG. 9 is a diagram illustrating a specific example of a recessed portion formation process;

FIG. 10 is a diagram illustrating a specific example of a seed layer formation process;

FIG. 11 is a diagram illustrating a specific example of a surface treatment layer formation process;

FIG. 12 is a diagram illustrating a specific example of an electrolytic plating process;

FIG. 13 is a diagram illustrating a specific example of a chemical mechanical polishing process;

FIG. 14 is a diagram illustrating a specific example of a build-up process;

FIG. 15 is a diagram illustrating a specific example of a solder resist layer formation process;

FIG. 16 is a diagram illustrating a specific example of a dicing process;

FIG. 17 is a diagram illustrating a specific example of a debonding process;

FIG. 18 is a diagram illustrating a specific example of a protection film lamination process;

FIG. 19 is a diagram illustrating a specific example of an inverting process;

FIG. 20 is a diagram illustrating a specific example of a metal layer removal process;

FIG. 21 is a diagram illustrating a specific example of an insulating layer etching process;

FIG. 22 is a diagram illustrating a specific example of a seed layer removal process;

FIG. 23 is a diagram illustrating a specific example of a protection film stripping process; and

FIG. 24 is a diagram illustrating a specific example of a semiconductor chip mounting process.

### DESCRIPTION OF EMBODIMENT

Embodiments of a wiring board, a semiconductor device, and a wiring board manufacturing method disclosed in the present application will be described in detail below based on the drawings. The disclosed technology is not limited by the embodiments below.

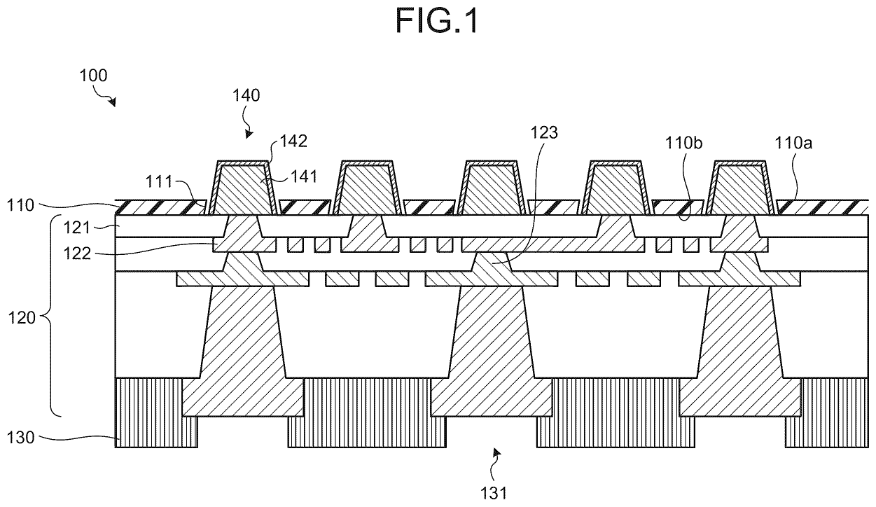

FIG. 1 is a diagram illustrating a configuration of a wiring board 100 according to one embodiment. FIG. 1 schematically illustrates a cross section of the wiring board 100. The wiring board 100 illustrated in FIG. 1 may be used as, for example, a substrate of a semiconductor device on which a semiconductor chip is mounted.

The wiring board 100 has a laminated structure, and includes an insulating layer 110, a multilayer wiring structure (one example of the wiring structure) 120, and a solder resist layer 130. In the following, as illustrated in FIG. 1, explanation will be given based on the assumption that the solder resist layer 130 serves as a lowermost layer and the insulating layer 110 serves as an uppermost layer; however, the wiring board 100 may be used in an inverted manner or may be used in an arbitrary posture, for example.

The insulating layer 110 is formed by using, for example, insulating resin, such as epoxy resin, polyimide resin, or cyanate resin, that has heat-resistant property, non-photosensitive property, and a thermosetting property. A thickness of the insulating layer 110 may be set to, for example, about 1 to 10 micrometers (μm). The insulating layer 110 may include a filler, such as silica (SiO₂).

A surface of the wiring board 100 at the side of the insulating layer 110 is a surface on which an electronic component, such as a semiconductor chip, is to be mounted, for example. At a mounting position of the semiconductor chip, opening portions 111 that penetrate through an upper surface 110a and a lower surface 110b of the insulating layer 110 are formed in the insulating layer 110. Specifically, the opening portions 111 are arranged in the insulating layer 110 to connect electrodes of the semiconductor chip and the multilayer wiring structure 120. The insulating layer 110 is formed by using non-photosensitive and thermosetting resin, and therefore, the opening portions 111 may be formed by, for example, laser processing. Further, connection terminals 140 for connecting the electrodes of the semiconductor chip and the multilayer wiring structure 120 are arranged in the opening portions 111. A configuration of the connection terminals 140 will be described later.

The multilayer wiring structure 120 is configured such that a layer including an insulating layer 121 that has insulating property and wiring layers 122 that have conductive property are laminated on the lower surface 110b of the insulating layer 110. The insulating layer 121 is formed by using, for example, insulating resin, such as epoxy resin, polyimide resin, or cyanate resin, that has heat-resistant property, non-photosensitive property, and thermosetting property. Further, the wiring layers 122 are formed by using, for example, a metal, such as copper or a copper alloy. In FIG. 1, three layers are laminated in the multilayer wiring structure 120, but the number of laminated layers may be two or less, or four or more. The wiring layers 122 that are adjacent to each other via the insulating layer 121 may be connected to each other if needed, via vias 123 that penetrate through the insulating layer 121. Similarly, the wiring layer 122 and the connection terminals 140 that are adjacent to each other via the insulating layer 121 are connected to each other if needed, via the vias 123 that penetrate through the insulating layer 121.

The solder resist layer 130 is a layer that covers the wiring layer 122 serving as the lowermost layer of the multilayer wiring structure 120, and protects wiring. The solder resist layer 130 is a layer made of, for example, insulating resin, such as epoxy resin, polyimide resin, or cyanate resin, that has heat-resistant property, non-photosensitive property, and thermosetting property.

A surface of the wiring board 100 at the side of the solder resist layer 130 is a surface to be connected to an external component or an external device. At positions at which external connection terminals that are electrically connected to an external component or an external device are formed, opening portions 131 are formed in the solder resist layer 130, and the wiring layer 122 serving as the lowermost layer of the multilayer wiring structure 120 is exposed from the opening portions 131. In the opening portions 131, external connection terminals, such as solder balls, are formed, for example. The solder resist layer 130 is formed by using non-photosensitive and thermosetting resin, and therefore, the opening portions 131 may be formed by laser processing.

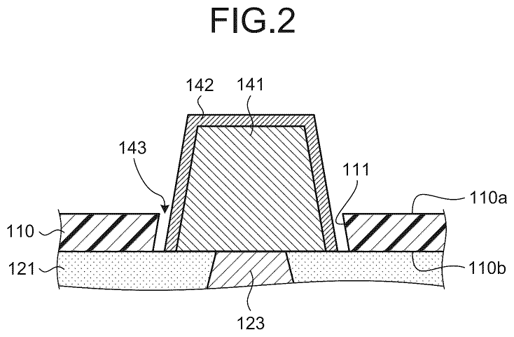

A configuration of each of the connection terminals 140 will be described in detail below with reference to FIG. 2. FIG. 2 is an enlarged view of a periphery of the connection terminal 140. The connection terminal 140 is a protruding electrode that is formed so as to protrude from the upper surface 110a of the insulating layer 110 at the position of the opening portion 111 in the insulating layer 110, and includes a pad 141 and a surface treatment layer 142.

The pad 141 is an electrode that serves as a main body of the connection terminal 140, and is formed in the opening portion 111 of the insulating layer 110 by electrolytic copper (Cu) plating, for example. A bottom surface of the pad 141 is located on the same plane as the lower surface 110b of the insulating layer 110. A height of the pad 141 (height of an upper portion from the upper surface 110a of the insulating layer 110 without including a portion in the opening portion 111) may be set to, for example, about 5 to 20 μm. Further, a pitch of the pad 141 may be set to, for example, about 20 to 150 μm.

The surface treatment layer 142 is a metal layer that covers an upper surface and side surfaces of the pad 141. The surface treatment layer 142 includes a nickel (Ni) layer, a palladium (Pd) layer, and a gold (Au) layer in this order from the closest to the pad 141. Each of the Ni layer, the Pd layer, and the Au layer may be formed by, for example, an electrolytic plating method. Meanwhile, as the surface treatment layer 142, a Ni/Au layer or an Au layer may be used instead of the Ni/Pd/Au layer.

A configuration of the connection terminal 140 around the opening portion 111 of the insulating layer 110 will be described below. The pad 141 protrudes from the upper surface 110a of the insulating layer 110 at the position of the opening portion 111. The pad 141 has a smaller diameter than the opening portion 111, and located away from an inner wall surface of the opening portion 111. Therefore, the surface treatment layer 142 that covers the upper surface and the side surfaces of the pad 141 does not come into contact with the inner wall surface of the opening portion 111, and a gap 143 is generated between the surface treatment layer 142 and the inner wall surface of the opening portion 111. Specifically, the side surfaces of the pad 141 are located on the center side of the opening portion 111 as compared to the inner wall surface of the opening portion 111, and therefore, in lower portions of the side surfaces of the pad 141, the gap 143 that is sandwiched between the Au layer serving as an outermost layer of the surface treatment layer 142 and the inner wall surface of the opening portion 111 and that is connected to the upper surface 110a of the insulating layer 110 is formed. A width of the gap 143 (that is, a distance from the Au layer of the surface treatment layer 142 to the inner wall surface of the opening portion 111) is set to, for example, about 100 to 1500 nanometers (nm).

In one embodiment, with formation of the gap 143, a channel from the upper surface 110a of the insulating layer 110 to the opening portion 111 is formed. Therefore, for example, when a space between the wiring board 100 and the semiconductor chip is filled with an underfill material, a part of the underfill material that comes into contact with the upper surface 110a of the insulating layer 110 flows into the gap 143. As a result, it is possible to produce an anchor effect between the insulating layer 110 and the underfill material, so that it is possible to increase adhesiveness of the underfill material to the insulating layer 110. Further, it is possible to increase a length of a path extending along an interface between the insulating layer 110 and the underfill material between the adjacent connection terminals 140, so that it is possible to prevent occurrence of ion migration.

Furthermore, in one embodiment, the pad 141 has a tapered shape in which a diameter increases from the upper surface to the bottom surface. With the tapered shape of the pad 141, it is possible to increase a contact area between the surface treatment layer 142 on the side surfaces of the pad 141 and the underfill material as compared to a case in which the pad 141 has a rectangular shape, so that it is possible to increase the adhesiveness of the underfill material to the connection terminal 140.

Moreover, in one embodiment, the inner wall surface of the opening portion 111 is a tapered surface that is inclined, in a cross-sectional shape, in accordance with the tapered shape of the pad 141. Because the inner wall surface of the opening portions 111 is the tapered surface, it is possible to prevent the underfill material that has flown into the gap 143 from flowing out of the gap 143, so that it is possible to further increase the adhesiveness of the underfill material to the insulating layer 110.

Furthermore, in one embodiment, the width of the gap 143 (that is, the distance from the Au layer of the surface treatment layer 142 to the inner wall surface of the opening portion 111) is smaller than a thickness of the surface treatment layer 142. With this configuration, it is possible to cause a capillary phenomenon to occur with respect to the underfill material that flows into the gap 143, so that is possible to increase a filling efficiency of the underfill material with respect to the gap 143.

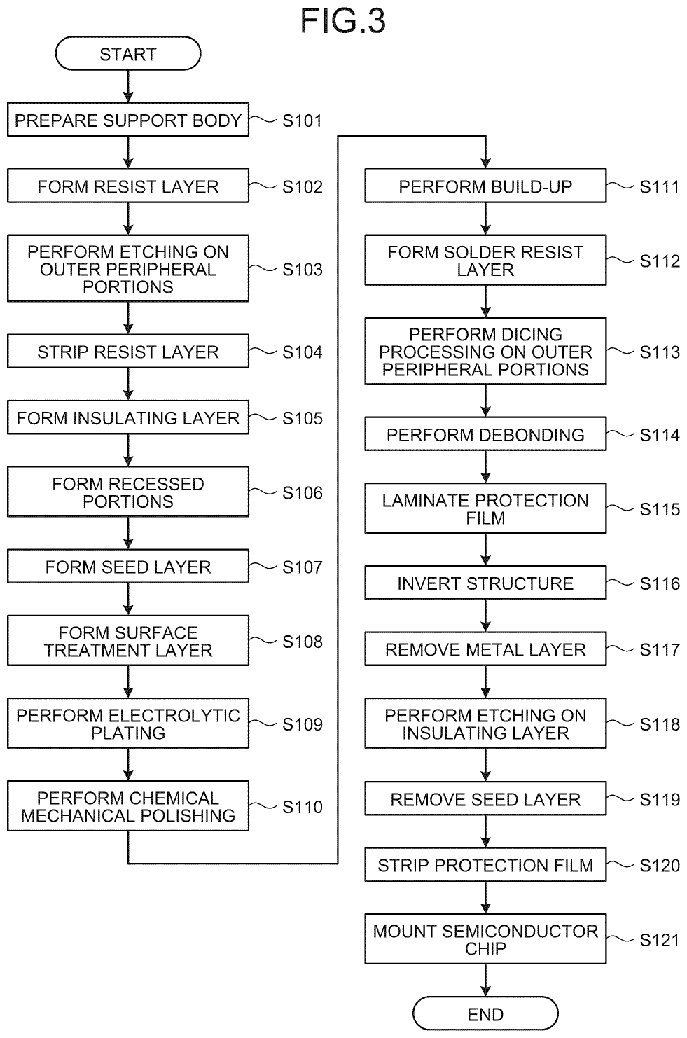

A method of manufacturing a semiconductor device including the wiring board 100 configured as described above will be described below with a specific example with reference to FIG. 3. FIG. 3 is a flowchart illustrating a method of manufacturing a semiconductor device according to one embodiment.

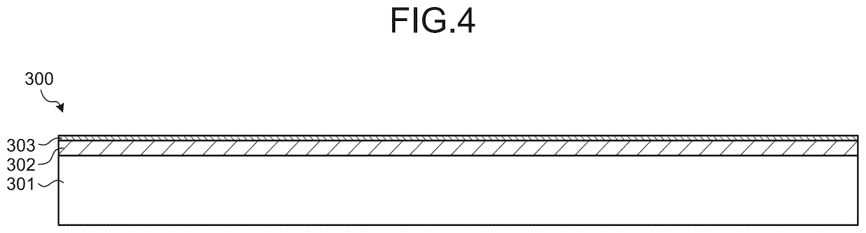

First, a support body 300 for manufacturing the wiring board 100 is prepared (Step S101). Specifically, as illustrated in FIG. 4 for example, the support body 300 in which a first metal layer 302 and a second metal layer 303 are laminated in this order on a base 301 is prepared. FIG. 4 is a diagram illustrating a specific example of the support body 300. As the base 301, for example, a glass plate or the like is used. The first metal layer 302 and the second metal layer 303 are formed by using, for example, copper or a copper alloy. The second metal layer 303 is a metal layer that has a smaller thickness than the first metal layer 302, and is formed in a strippable manner on the first metal layer 302 via a release layer (not illustrated).

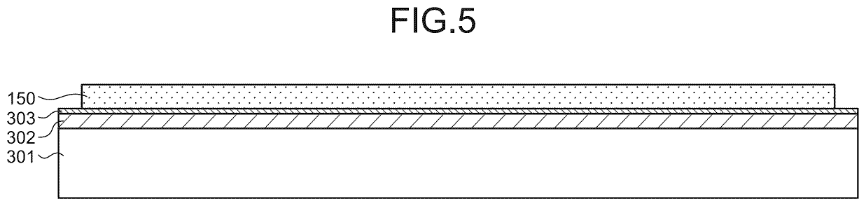

Subsequently, a resist layer is formed on the second metal layer 303 (Step S102). Specifically, as illustrated in FIG. 5 for example, a resist layer 150 that covers the second metal layer 303 except for outer peripheral portions of the second metal layer 303 is formed. FIG. 5 is a diagram illustrating a specific example of a resist layer formation process. The resist layer 150 is formed by using, for example, a dry film resist, and a part of the resist layer 150 corresponding to the outer peripheral portions of the second metal layer 303 is removed by photolithography or laser processing.

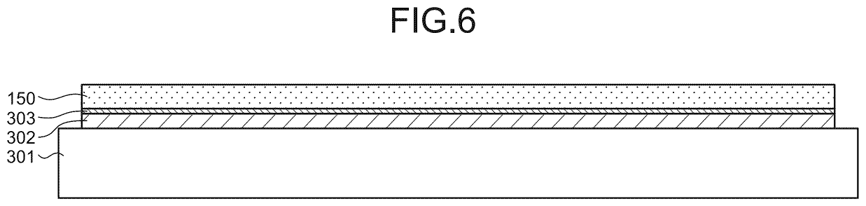

Then, outer peripheral portions of the second metal layer 303 and the first metal layer 302 are removed by etching (Step S103). Specifically, as illustrated in FIG. 6 for example, the outer peripheral portions of the second metal layer 303 and the first metal layer 302 that are not covered by the resist layer 150 are removed. In other words, the outer peripheral portions of the second metal layer 303 and the first metal layer 302 are removed such that side end portions of the second metal layer 303 and the first metal layer 302 are located on inner sides of side end portions of the base 301. With this configuration, the side end portions of the second metal layer 303 and the first metal layer 302 are covered and protected by the insulating layer 110 in a subsequent process, so that it becomes possible to prevent stripping of the second metal layer 303 and the first metal layer 302 due to penetration of a chemical solution during a manufacturing process of the wiring board 100. FIG. 6 is a diagram illustrating a specific example of an outer peripheral portion etching process.

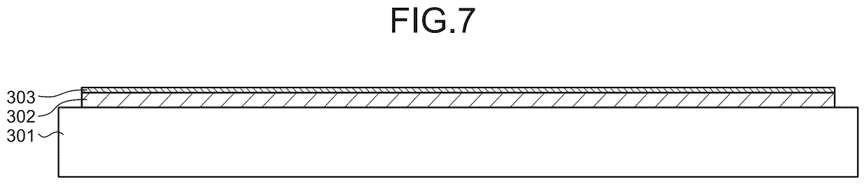

Subsequently, the resist layer 150 is stripped (Step S104). An alkaline stripping solution of caustic soda or an amine system is used to strip the resist layer 150, for example. By stripping of the resist layer 150, as illustrated in FIG. 7 for example, the second metal layer 303 is exposed. FIG. 7 is a diagram illustrating a specific example of a resist layer stripping process.

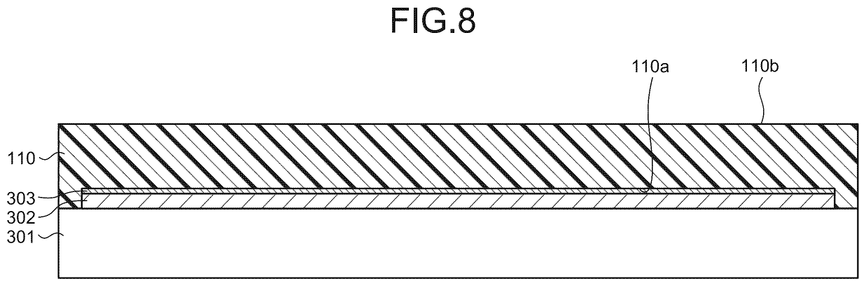

After the second metal layer 303 is exposed, the insulating layer 110 is formed on the second metal layer 303 (Step S105). Specifically, as illustrated in FIG. 8 for example, the insulating layer 110 in a semi-cured state is laminated on the second metal layer 303. At this time, the side end portions of the second metal layer 303 and the first metal layer 302 are covered by the insulating layer 110. The insulating layer 110 laminated on the second metal layer 303 is thermally cured. FIG. 8 is a diagram illustrating a specific example of an insulating layer formation process. In FIG. 8, a surface of the insulating layer 110 that comes into contact with an upper surface of the second metal layer 303 serves as the upper surface 110a, and a surface of the insulating layer 110 located opposite to the second metal layer 303 serves as the lower surface 110b.

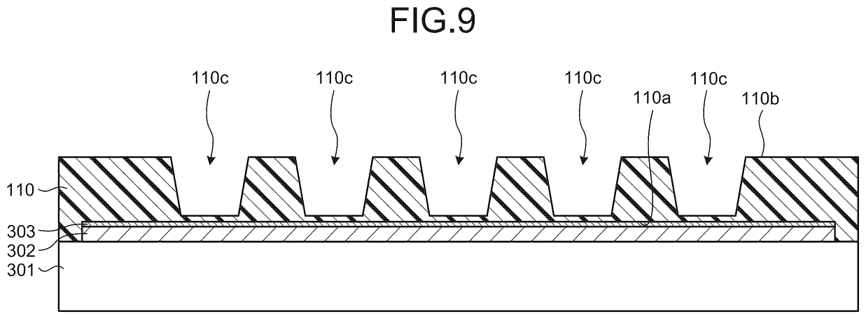

After formation of the insulating layer 110 on the second metal layer 303, recessed portions are formed in the lower surface 110b of the insulating layer 110 (Step S106). Specifically, as illustrated in FIG. 9 for example, recessed portions 110c that do not reach the second metal layer 303 are formed in the lower surface 110b of the insulating layer 110. FIG. 9 is a diagram illustrating a specific example of a recessed portion formation process. The recessed portions 110c have tapered shapes in which diameters are reduced from opening surfaces (top portions) to bottom portions. The recessed portions 110c may be formed by, for example, a laser processing method or the like using CO₂ laser, ultraviolet (UV) laser, or excimer laser.

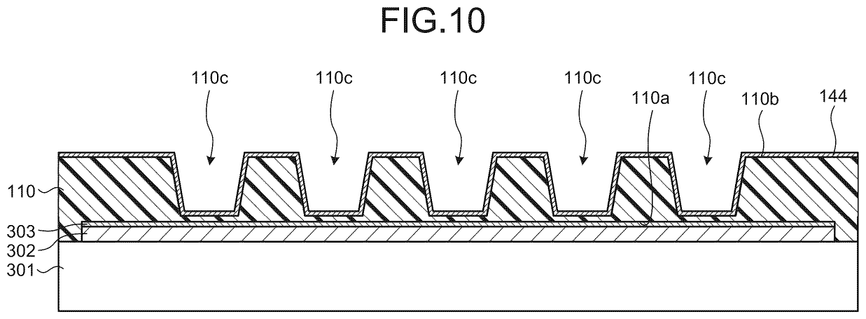

After formation of the recessed portions 110c, a seed layer 144 is formed on the lower surface 110b of the insulating layer 110 (Step S107). Specifically, as illustrated in FIG. 10 for example, the seed layer 144 that continuously covers the lower surface 110b of the insulating layer 110 around the recessed portions 110c and inner wall surfaces of the recessed portions 110c is formed by, for example, an electroless plating method. FIG. 10 is a diagram illustrating a specific example of a seed layer formation process. As a material of the seed layer 144, for example, copper (Cu) or the like may be used. A thickness of the seed layer 144 defines the width of the gap 143, and may be set to, for example, about 100 to 1500 nm.

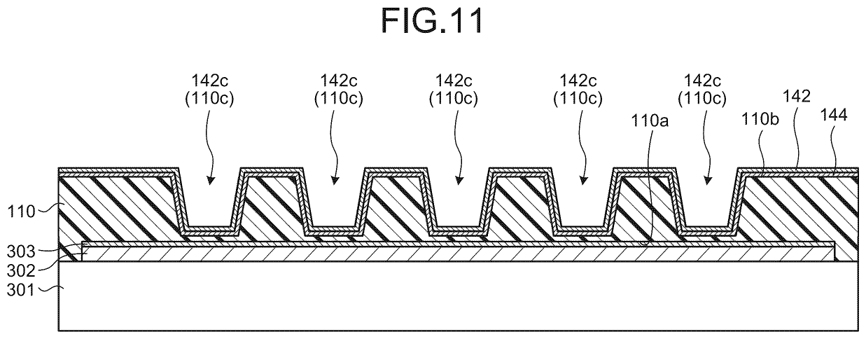

After formation of the seed layer 144, the surface treatment layer 142 is formed on the seed layer 144 in an overlapping manner (Step S108). Specifically, as illustrated in FIG. 11 for example, the surface treatment layer 142 that continuously covers the seed layer 144 is formed by, for example, an electrolytic plating method. FIG. 11 is a diagram illustrating a specific example of a surface treatment layer formation process. When the surface treatment layer 142 is formed by the electrolytic plating method, an Au layer, a Pd layer, and a Ni layer are laminated in this order on a surface of the seed layer 144. With formation of the surface treatment layer 142 by the electrolytic plating method, it is possible to prevent a chipping failure in which the surface treatment layer 142 is chipped on the surface of the seed layer 144.

When the surface treatment layer 142 is formed, the recessed portions 110c are subjected to electrolytic plating with a uniform thickness. Therefore, the upper surface of the surface treatment layer 142 includes recessed portions 142c that correspond to the recessed portions 110c.

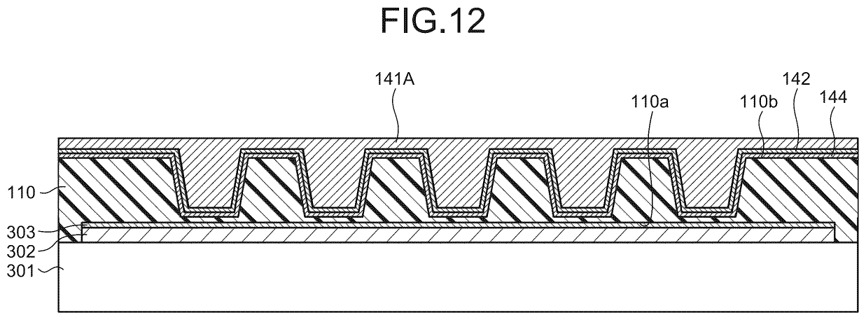

After formation of the surface treatment layer 142, as illustrated in FIG. 12 for example, a metal film 141A is formed on the entire surface of the surface treatment layer 142 by, for example, an electrolytic plating method (Step S109). FIG. 12 is a diagram illustrating a specific example of an electrolytic plating process. The metal film 141A is filled into the recessed portions 142c of the surface treatment layer 142.

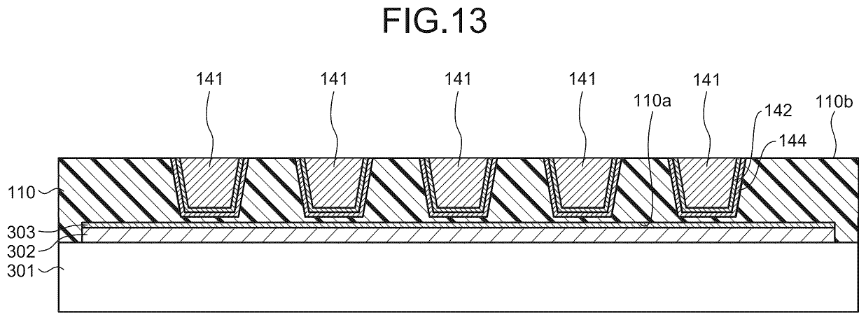

Subsequently, an entire surface of the metal film 141A is polished by, for example, Chemical Mechanical Polishing (CMP) (Step S110), so that, as illustrated in FIG. 13 for example, the lower surface 110b of the insulating layer 110 is exposed. FIG. 13 is a diagram illustrating a specific example of a chemical mechanical polishing process. In the polishing process, the metal film 141A remains in the recessed portions 142c of the surface treatment layer 142, and the remaining metal film 141A forms the pads 141 that have the bottom surfaces located on the same plane as the lower surface 110b of the insulating layer 110. The bottom surfaces of the pads 141 are formed at the side of the opening surfaces (top portions) of the recessed portions 110c of the insulating layer 110, and the upper surfaces of the pads 141 are formed at the side of the bottom surfaces of the recessed portions 110c.

Further, in the polishing process, the seed layer 144 and the surface treatment layer 142 on the lower surface 110b of the insulating layer 110 are polished and removed together with the metal film 141A. Furthermore, the seed layer 144 and the surface treatment layer 142 that remain without being removed by the polishing cover the upper surfaces and the side surfaces of the pads 141. Accordingly, the connection terminals 140 that include the pads 141 and the surface treatment layer 142 that coves the upper surfaces and the side surfaces of the pads 141 are obtained. At this stage, the connection terminals 140 are embedded in the insulating layer 110.

Polishing by CMP is completed when the recessed portions 110c of the insulating layer 110 reach appropriate depths. For example, the metal film 141A, the surface treatment layer 142, the seed layer 144, and the lower surface 110b of the insulating layer 110 are polished in a depth direction of the recessed portions 110c until the depths of the recessed portions 110c of the insulating layer 110 are reduced by about 1 to 5 μm from initial depths. For example, when diameters of the bottom portions of the recessed portions 110c are 13 μm and diameters of the top portions are 20 μm in initial states, and if polishing is performed by about 5 μm in the depth direction of the recessed portions 110c, the diameters of the polished recessed portions 110c becomes about 18 μm. The bottom surfaces of the pads 141 are formed at the side of the top portions of the recessed portions 110c, so that it is possible to fully ensure areas of the bottom surfaces of the pads 141, and improve connection reliability between the vias of the multilayer wiring structure 120 that is laminated in a subsequent process and the bottom surfaces of the pads 141.

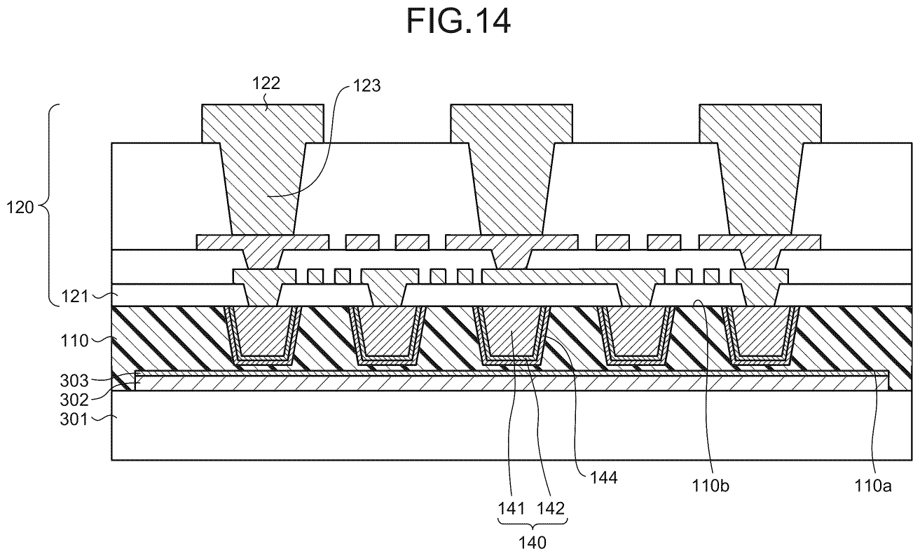

The lower surface 110b of the insulating layer 110 is made flat by the polishing, and therefore, the multilayer wiring structure 120 is formed on the lower surface 110b by a build-up method (Step S111). Specifically, as illustrated in FIG. 14 for example, the insulating layer 121 is formed on the lower surface 110b of the insulating layer 110, and the wiring layers 122 are formed on the surface of the insulating layer 121. FIG. 14 is a diagram illustrating a specific example of a build-up process. The insulating layer 121 is formed by using insulating resin, such as epoxy resin or polyimide resin, for example. Further, the wiring layers 122 are formed by metal plating using copper or the like, for example.

Spaces between the connection terminals 140 (the pads 141) embedded in the insulating layer 110 and the wiring layer 122 or a space between the adjacent wiring layers 122 are connected if needed via the vias 123 that are formed by, for example, metal plating using copper or the like. It may be possible to laminate the plurality of insulating layers 121 and the plurality of wiring layers 122 on the lower surface 110b of the insulating layer 110.

After formation of the multilayer wiring structure 120, the wiring layer 122 on the surface of the multilayer wiring structure 120 is covered by the solder resist layer 130 (Step S112). The solder resist layer 130 is formed by using, as a material, resin, such as epoxy resin, polyimide resin, or cyanate resin, that has heat-resistant property, non-photosensitive property, and thermosetting property, for example.

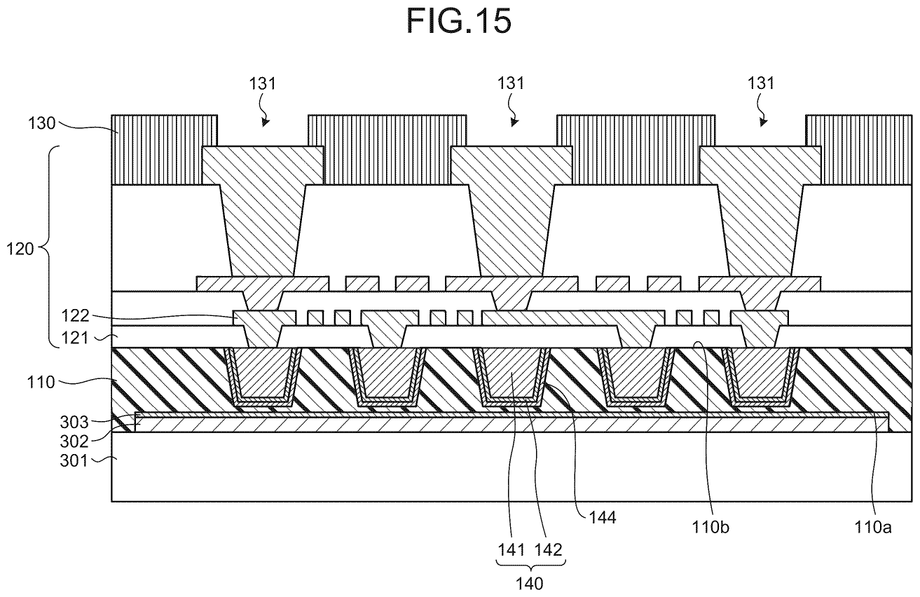

Further, as illustrated in FIG. 15 for example, the opening portions 131 are formed in the solder resist layer 130 at positions at which external connection terminals are arranged on a side on which an external component or an external device is to be connected. FIG. 15 is a diagram illustrating a specific example of a solder resist layer formation process. The wiring layer 122 that is an outermost layer of the multilayer wiring structure 120 is exposed at the bottom surfaces of the opening portions 131. The solder resist layer 130 is made of non-photosensitive resin, and therefore, the opening portions 131 are formed by laser processing. In the laser processing, for example, CO₂ laser, UV laser, or the like may be used.

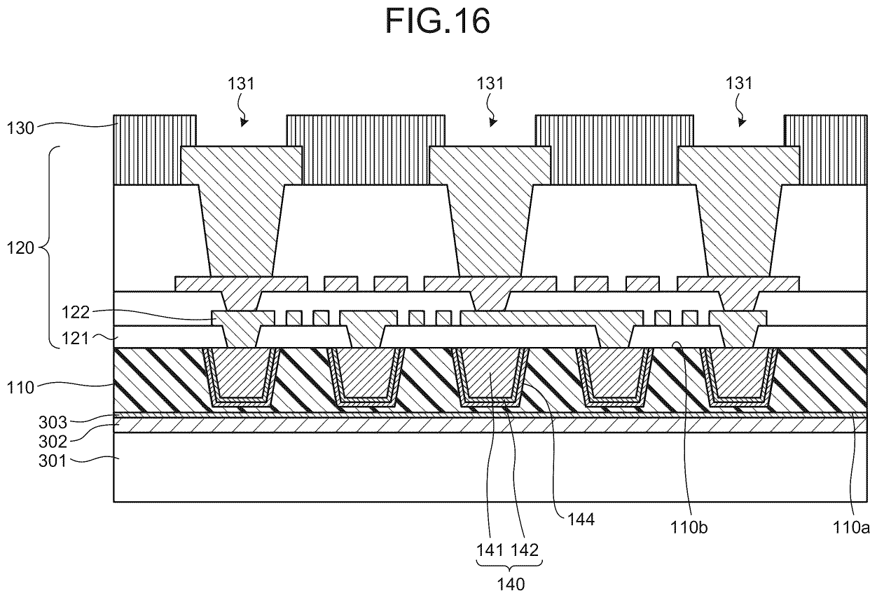

Subsequently, outer peripheral portions of the base 301 of the support body 300 and the solder resist layer 130 are removed by, for example, dicing processing (Step S113). Specifically, as illustrated in FIG. 16 for example, outer peripheries of side end portions of the base 301 are cut and removed, together with the solder resist layer 130, the multilayer wiring structure 120, and the insulating layer 110. Accordingly, the side end portions of the second metal layer 303 and the first metal layer 302 are exposed. FIG. 16 is a diagram illustrating a specific example of a dicing process.

By removal of the outer peripheral portions of the base 301 and the solder resist layer 130 of the support body 300, an intermediate structure of the wiring board 100 is obtained. Specifically, the intermediate structure in which the insulating layer 110, the multilayer wiring structure 120, and the solder resist layer 130 are laminated on the support body 300 is formed. The insulating layer 110, the multilayer wiring structure 120, and the solder resist layer 130 constitute the wiring board 100.

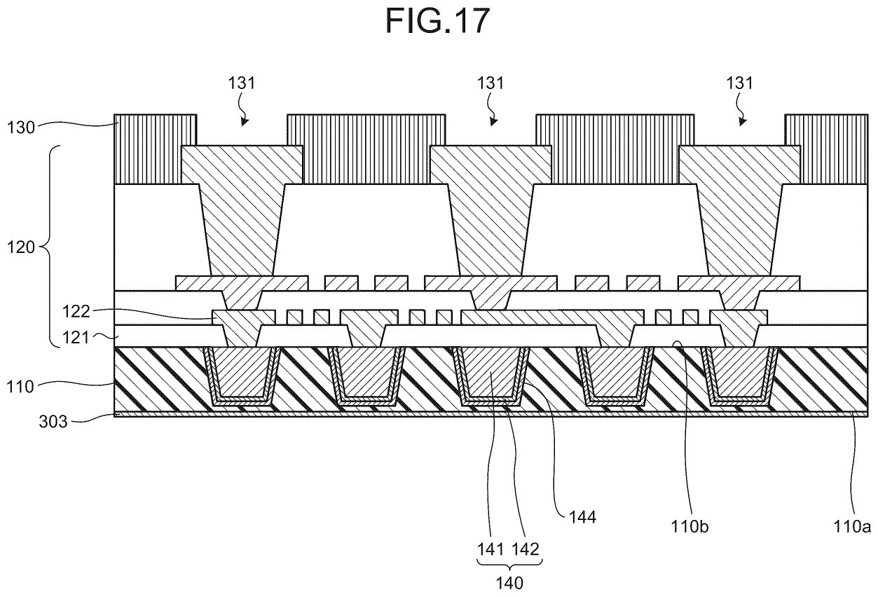

Subsequently, a portion including the insulating layer 110, the multilayer wiring structure 120, and the solder resist layer 130 is debonded from the intermediate structure (Step S114). Specifically, as illustrated in FIG. 17 for example, the second metal layer 303 and upper layers of the second metal layer 303 are stripped from the first metal layer 302 of the intermediate structure, so that a second intermediate structure including the insulating layer 110, the multilayer wiring structure 120, and the solder resist layer 130 is obtained. FIG. 17 is a diagram illustrating a specific example of a debonding process. The second metal layer 303 remains on the upper surface 110a of the insulating layer 110 in the second intermediate structure.

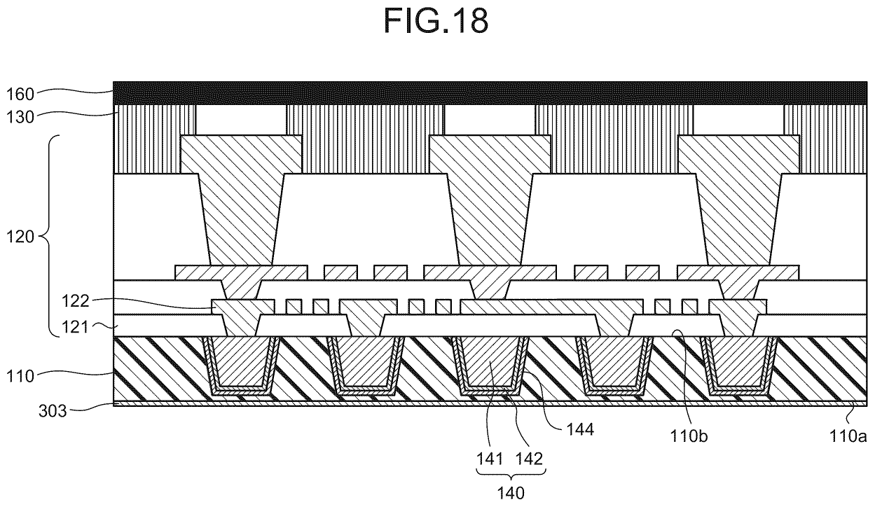

Then, to protect the solder resist layer 130 side, as illustrated in FIG. 18 for example, a protection film 160 is laminated on a surface of the solder resist layer 130 (Step S115). FIG. 18 is a diagram illustrating a specific example of a protection film lamination process.

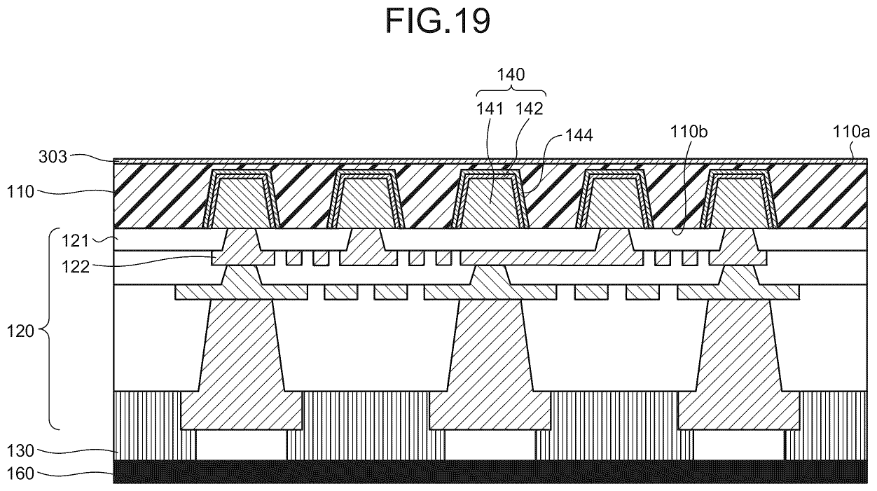

Subsequently, the second intermediate structure is inverted as illustrated in FIG. 19 for example (Step S116). Accordingly, the solder resist layer 130 serves as a lowermost layer, and the insulating layer 110 serves as an uppermost layer. FIG. 19 is a diagram illustrating a specific example of an inverting process.

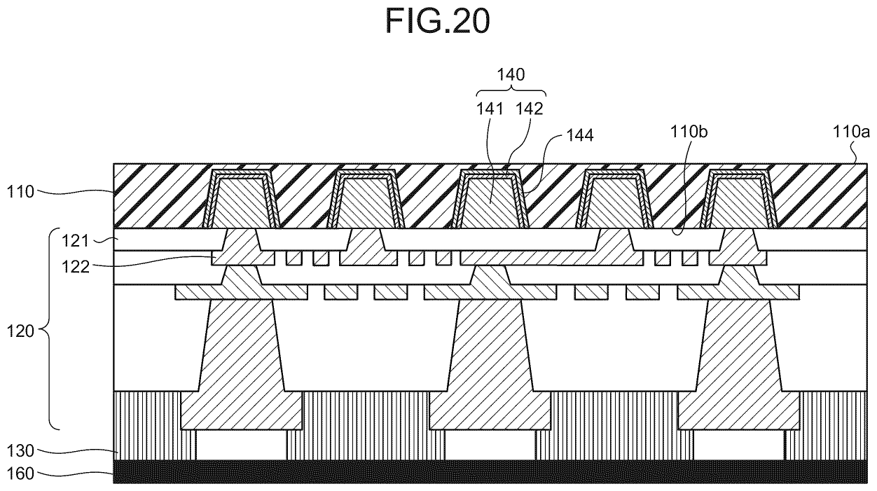

Then, the second metal layer 303 that remains on the upper surface 110a of the insulating layer 110 is removed by wet etching (Step S117), and, as illustrated in FIG. 20 for example, the upper surface 110a of the insulating layer 110 is exposed. FIG. 20 is a diagram illustrating a specific example of a metal layer removal process.

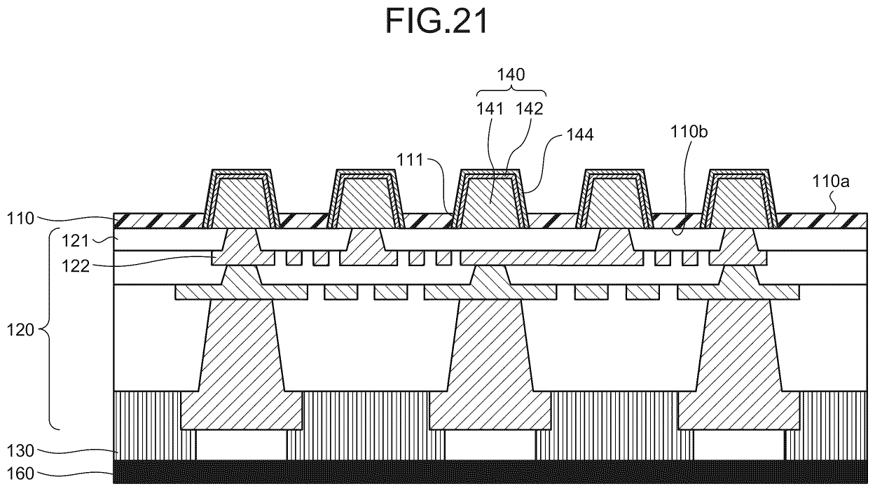

After the upper surface 110a of the insulating layer 110 is exposed, the insulating layer 110 is etched from the upper surface 110a (Step S118). Accordingly, as illustrated in FIG. 21 for example, the opening portions 111 are formed at the positions of the recessed portions 110c of the insulating layer 110, and the pads 141 protrude from the upper surface 110a of the insulating layer 110 at the positions of the opening portions 111. FIG. 21 is a diagram illustrating a specific example of an insulating layer etching process. Etching of the insulating layer 110 is realized by dry etching using plasm, excimer laser, or the like, for example. Etching of the insulating layer 110 is completed when a thickness of the remaining insulating layer 110 reaches an appropriate thickness. For example, the insulating layer 110 is etched until the heights of the pads 141 (heights of upper portions from the upper surface 110a of the insulating layer 110 without including portions in the opening portions 111) reaches about 5 to 20 μm, for example.

The insulating layer 110 is etched from the upper surface 110a, so that the upper surface 110a is roughened. Therefore, in the insulating layer 110, surface roughness of the upper surface 110a increases as compared to surface roughness of the lower surface 110b. Due to the increase in the surface roughness of the upper surface 110a as compared to the lower surface 110b, a contact area between the underfill material that is filled in a space formed with a semiconductor chip in a subsequent process and the insulating layer 110 increases, so that adhesiveness of the underfill material to the insulating layer 110 is further increased.

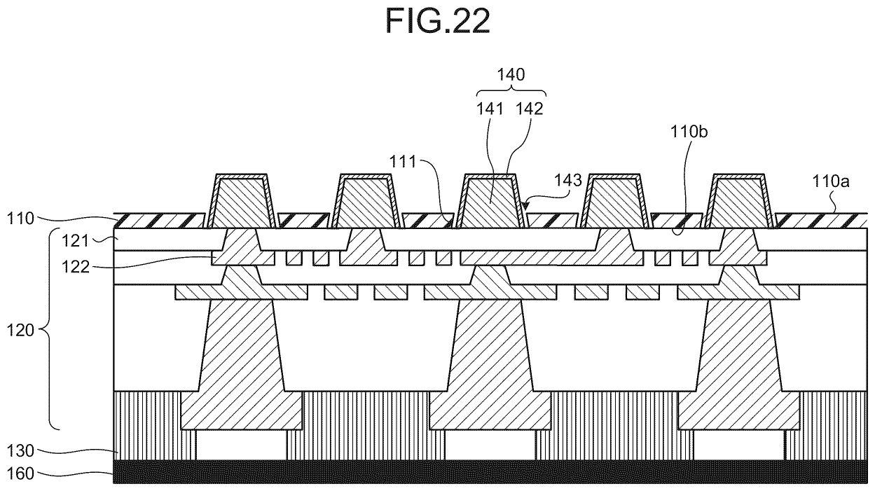

At a stage at which the pads 141 protrude from the upper surface 110a of the insulating layer 110 at the positions of the opening portions 111 due to etching of the insulating layer 110, the seed layer 144 remains on the surface treatment layer 142 of the connection terminals 140. Therefore, as illustrated in FIG. 22 for example, the seed layer 144 is removed from the surface treatment layer 142 by etching (Step S119). Specifically, the seed layer 144 that is made of copper (Cu) is removed by wet etching using an etching solution, such as sulfuric acid-hydrogen peroxide or persulfate, for example. Accordingly, the gaps 143 with the same thicknesses as the seed layer 144 are formed between the surface treatment layer 142 and the inner wall surfaces of the opening portions 111. FIG. 22 is a diagram illustrating a specific example of a seed layer removal process.

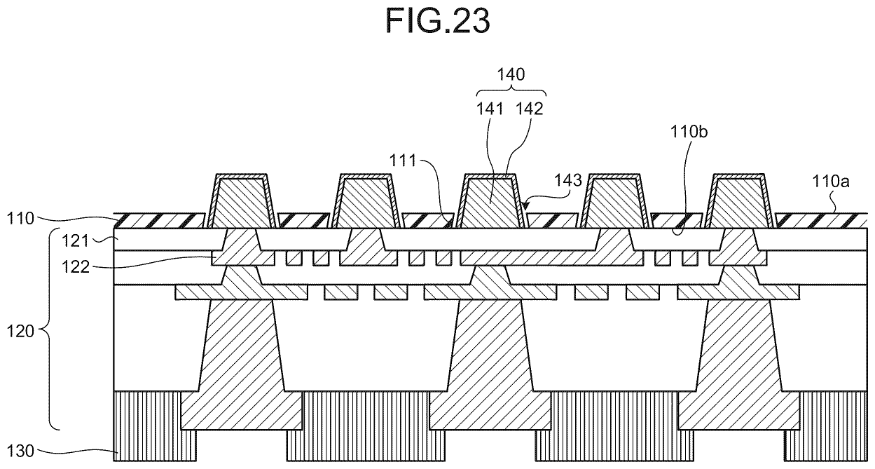

After removal of the seed layer 144, as illustrated in FIG. 23 for example, the protection film 160 is stripped from the surface of the solder resist layer 130 (Step S120). FIG. 23 is a diagram illustrating a specific example of a protection film stripping process.

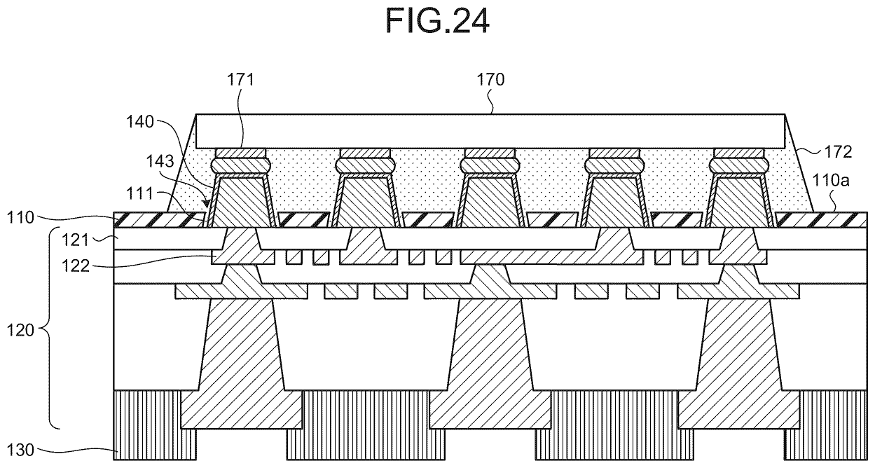

After stripping of the protection film 160 from the solder resist layer 130, a semiconductor chip is mounted at the side of the insulating layer 110 (Step S121), and the connection terminals 140 and electrodes of the semiconductor chip are connected. Specifically, as illustrated in FIG. 24 for example, a semiconductor chip 170 is mounted on upper parts of the connection terminals 140, and electrodes 171 of the semiconductor chip 170 are connected to the connection terminals 140 by, for example, solder or the like. FIG. 24 is a diagram illustrating a specific example of a semiconductor chip mounting process.

Then, after bonding of the electrodes 171 and the connection terminals 140, a space between the wiring board 100 and the semiconductor chip 170 is filled with an underfill material 172. Bonding portions between the electrodes 171 and the connection terminals 140 are sealed with the underfill material 172, so that a semiconductor device in which the semiconductor chip 170 is mounted on the wiring board 100 is obtained.

When the underfill material 172 is filled, the upper surface 110a of the insulating layer 110 comes into contact with the underfill material 172. In the present embodiment, the gaps 143 are formed between lower outer circumferences of the connection terminals 140 (the surface treatment layer 142) and the inner wall surfaces of the opening portions 111 of the insulating layer 110, so that a part of the underfill material 172 that comes into contact with the upper surface 110a of the insulating layer 110 flows into the gaps 143. As a result, it is possible to produce the anchor effect between the insulating layer 110 and the underfill material 172, so that it is possible to increase adhesiveness of the underfill material 172 to the insulating layer 110.

As described above, a wiring board (as one example, the wiring board 100) according to one embodiment includes an insulating layer (as one example, the insulating layer 110), a connection terminal (as one example, the connection terminal 140), and a wiring structure (as one example, the multilayer wiring structure 120). The insulating layer includes a first surface (as one example, the upper surface 110a) and a second surface (as one example, the lower surface 110b) on an opposite side of the first surface, and includes an opening portion (as one example, the opening portion 111) that is formed so as to penetrate through the first surface and the second surface. The connection terminal is arranged in the opening portion. The wiring structure is laminated on the second surface of the insulating layer and connected to the connection terminal. The connection terminal includes a pad (as one example, the pad 141) that is formed in the opening portion and that has a bottom surface located on the same plane as the second surface of the insulating layer, and a surface treatment layer (as one example, the surface treatment layer 142) that covers an upper surface and side surfaces of the pad. The pad protrudes from the first surface of the insulating layer at a position of the opening portion, and a gap (as one example, the gap 143) is formed between the surface treatment layer and an inner wall surface of the opening portion. With this configuration, it is possible to increase adhesiveness of an underfill material (as one example, the underfill material 172) to the insulating layer.

Furthermore, the pad may have a tapered shape in which a diameter increases from the upper surface to the bottom surface. With this configuration, it is possible to increase adhesiveness of the underfill material to the connection terminal.

Moreover, the inner wall surface of the opening portion may be a tapered surface that is inclined, in a cross-sectional shape, in accordance with the tapered shape of the pad. With this configuration, it is possible to further increase adhesiveness of the underfill material to the connection terminal.

Furthermore, the surface treatment layer may include the gap with a smaller width than a thickness of the surface treatment layer, in a space formed with the inner wall surface of the opening portion. With this configuration, it is possible to increase a filling efficiency of the underfill material with respect to the gap.

Moreover, in the insulating layer, surface roughness of the first surface may be larger than surface roughness of the second surface. With this configuration, it is possible to further increase adhesiveness of the underfill material to the insulating layer.

According to one embodiment of the wiring board disclosed in the present application, it is possible to increase adhesiveness of an underfill material to an insulating layer.

(Note) A wiring board manufacturing method comprising:
preparing a support body in which a first metal layer and a second metal layer are formed in sequence on a base;
forming, on the second metal layer, an insulating layer that includes a first surface coming into contact with the second metal layer and a second surface on an opposite side of the first surface;
forming, on the second surface of the insulating layer, a recessed portion that does not reach the second metal layer;
forming a seed layer that covers the second surface of the insulating layer around the recessed portion and an inner wall surface of the recessed portion;
forming a surface treatment layer on the seed layer in an overlapping manner;
forming a metal film for filling a recessed portion, the recessed portion being formed in the surface treatment layer in accordance with a position of the recessed portion of the insulating layer;
polishing the seed layer and the surface treatment layer on the second surface of the insulating layer as well as polishing the metal film so as to form, by the metal film that remains in the recessed portion of the surface treatment layer, a pad that has a bottom surface located on a same plane as the second surface of the insulating layer;
forming a wiring structure that is connected to the pad, on the second surface of the insulating layer;
stripping the second metal layer from the first metal layer;
exposing the first surface of the insulating layer by removing the second metal layer;
etching the insulating layer from the first surface so as to form an opening portion that penetrates through the first surface and the second surface of the insulating layer at the position of the recessed portion of the insulating layer, and so as to cause the pad to protrude from the first surface of the insulating layer at a position of the opening portion; and
forming a gap between the surface treatment layer and an inner wall surface of the opening portion by removing the seed layer from the surface treatment layer that covers an upper surface and side surfaces of the pad.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A wiring board comprising:
an insulating layer that includes a first surface and a second surface on an opposite side of the first surface, and includes an opening portion that is formed so as to penetrate through the first surface and the second surface;
a connection terminal that is arranged in the opening portion; and
a wiring structure that is formed on the second surface of the insulating layer and connected to the connection terminal, wherein
the connection terminal includes
a pad that is formed in the opening portion and that has a bottom surface located on a same plane as the second surface of the insulating layer; and
a surface treatment layer that covers an upper surface and side surfaces of the pad,
the pad protrudes from the first surface of the insulating layer at a position of the opening portion, and
the surface treatment layer forms a gap between the surface treatment layer and an inner wall surface of the opening portion.

2. The wiring board according to claim 1, wherein the pad has a tapered shape in which a diameter increases from the upper surface to the bottom surface.

3. The wiring board according to claim 2, wherein the inner wall surface of the opening portion is a tapered surface that is inclined, in a cross-sectional shape, in accordance with the tapered shape of the pad.

4. The wiring board according to claim 1, wherein the surface treatment layer forms the gap with a width smaller than a thickness of the surface treatment layer, in a space formed with the inner wall surface of the opening portion.

5. The wiring board according to claim 1, wherein, in the insulating layer, surface roughness of the first surface is larger than surface roughness of the second surface.

6. The wiring board according to claim 1, wherein the surface treatment layer and the pad are formed of mutually different metals.

7. The wiring board according to claim 1, wherein the wiring structure includes a third surface contacting with the second surface of the insulating layer, and
the third surface has a area that is not covered with the insulating layer and the connection terminal and that faces the gap.

8. The wiring board according to claim 7, wherein the third surface contacts with the pad and the surface treatment layer.

9. A semiconductor device comprising:
a wiring board;
a semiconductor chip that is mounted on the wiring board; and
an underfill material that is filled in a space between the wiring board and the semiconductor chip, wherein
the wiring board includes
an insulating layer that includes a first surface coming into contact with the underfill material and a second surface on an opposite side of the first surface, and includes an opening portion that is formed so as to penetrate through the first surface and the second surface;
a connection terminal that is arranged in the opening portion; and
a wiring structure that is formed on the second surface of the insulating layer and connected to the connection terminal,
the connection terminal includes
a pad that is formed in the opening portion and that has a bottom surface located on a same plane as the second surface of the insulating layer; and
a surface treatment layer that covers an upper surface and side surfaces of the pad,
the pad protrudes from the first surface of the insulating layer at a position of the opening portion,
the surface treatment layer forms a gap between the surface treatment layer and an inner wall surface of the opening portion, and
the gap is filled with the underfill material.
